(19) United States
(12) Patent Application Publication
(10) Pub. No.: US 2014/0111279 A1
(43) Pub. Date: Apr. 24, 2014

(54) ENVELOPE TRACKING DISTRIBUTED AMPLIFIER

(71) Applicant: SAMSUNG ELECTRONICS CO., LTD, Suwon-si (KR)

(72) Inventor: Michael Brobston, Allen, TX (US)

(73) Assignee: Samsung Electronics Co., LTD, Suwon-si (KR)

(21) Appl. No.: 13/869,737

(22) Filed: Apr. 24, 2013

Related U.S. Application Data
(60) Provisional application No. 61/716,296, filed on Oct. 19, 2012.

(51) Int. Cl. H03F 3/60; H04B 15/00

(52) U.S. Cl. CPC H03F 3/605; H03F 3/607; H04B 15/00
USPC 330/286

(57) ABSTRACT

A system and method amplify a waveform in a wireless network. An envelope of a waveform is detected to form an envelope waveform. The envelope waveform is shaped to form a shaped waveform, the shaping based on one or more characteristics of a distributed amplifier. The shaped waveform is filtered to form a filtered waveform. The filtered waveform is amplified to form a first amplified waveform. The distributed amplifier amplifies at least a part the waveform based on the first amplified waveform to form a second amplified waveform.

### CLAIM OF PRIORITY

The present application claims priority to U.S. Provisional Patent Application Ser. No. 61/716,296, filed Oct. 19, 2012, entitled “ENVELOPE TRACKING DISTRIBUTED AMPLIFIER.” The content of the above-identified patent document is incorporated herein by reference.

### TECHNICAL FIELD

The present application relates generally to distributed amplifiers and, more specifically, to an envelope tracking distributed amplifier.

### BACKGROUND

Both wireless mobile devices and infrastructure equipment require power amplifier circuits that operate with high efficiency. The battery life of mobile devices is very dependent on its power amplifier efficiency. The capital cost and operating cost of infrastructure equipment is heavily dependent on its power amplifier efficiency. In the past, much focus has been placed on optimizing the efficiency of the power amplifiers. Using single stage common source transistor circuits or cascaded transistor circuit, the power amplifier is typically matched to a 50 ohm load using a resonant matching network. This type of matching typically results in a relatively narrow bandwidth (˜5%) over which the PA operates efficiently and provides adequate gain.

For this reason, multi-band mobile device must employ multiple power amplifiers that are each tuned for peak operation in a different band in order to support roaming demands. Likewise wireless operators are now deploying services simultaneously in multiple bands supporting legacy air interfaces in one band and broadband services such as LTE in a different band. This is forcing infrastructure equipment suppliers to now provide equipment that operates concurrently in multiple bands to avoid excessive redundant transceiver equipment at the cell site. In addition, with the eminent advent of carrier aggregation demands, the need for concurrent multi-band operation in both infrastructure equipment and mobile devices will continue to escalate.

### SUMMARY

A method to amplify a waveform in a wireless network is provided. The method includes detecting an envelope of a waveform to form an envelope waveform. The method also includes shaping the envelope waveform to form a shaped waveform. The shaping is based on one or more characteristics of a distributed amplifier. The method also includes filtering the shaped waveform to form a filtered waveform. The method further includes amplifying the filtered waveform to form a first amplified waveform and amplifying, by the distributed amplifier, at least a part the waveform based on the first amplified waveform to form a second amplified waveform.

A mobile station (MS) configured to amplify a waveform is provided. The MS includes a detector configured to detect an envelope of the waveform to form an envelope waveform. The MS also includes a shaper configured to shape the envelope waveform to form a shaped waveform based on one or more characteristics of a distributed amplifier. The MS also includes a filter configured to filter the shaped waveform to form a filtered waveform. The MS further includes an envelope amplifier configured to amplify the filtered waveform to form a first amplified waveform and a distributed amplifier to amplify the waveform based on the first amplified waveform to form a second amplified waveform.

A base station (BS) configured to amplify a waveform is provided. The BS includes a digital signal processor configured to detect an envelope of the waveform to form an envelope waveform and shape the envelope waveform to form a shaped waveform based on one or more characteristics of a distributed amplifier. The BS also includes a filter configured to filter the shaped waveform to form a filtered waveform. The BS also includes an envelope amplifier configured to amplify the filtered waveform to form a first amplified waveform and a distributed amplifier to amplify the waveform based on the first amplified waveform to form a second amplified waveform.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates a wireless network according to embodiments of the present disclosure;

FIG. 2A illustrates a high-level diagram of a wireless transmit path according to embodiments of the present disclosure;

FIG. 2B illustrates a high-level diagram of a wireless receive path according to embodiments of the present disclosure;

FIG. 3 illustrates a subscriber station according to embodiments of the present disclosure;

FIG. 4 illustrates envelope tracking of a waveform according to embodiments of the present disclosure;

FIG. 5 illustrates a distributed amplifier according to embodiments of the present disclosure;

FIG. 6 illustrates a distributed amplifier configured with an envelope tracking path according to embodiments of the present disclosure;

FIG. 7 illustrates a distributed amplifier configured with an analog envelope tracking architecture according to embodiments of the present disclosure;

FIG. 8 illustrates a distributed amplifier configured with a digital envelope tracking architecture according to embodiments of the present disclosure;

FIG. 9 illustrates a distributed amplifier configured with a digital polar architecture according to embodiments of the present disclosure;

FIG. 10 illustrates a distributed amplifier configured with an analog polar architecture according to embodiments of the present disclosure; and

FIG. 11 is a flow diagram illustrating amplification of a waveform in a wireless network according to embodiments of the present disclosure.

### DETAILED DESCRIPTION

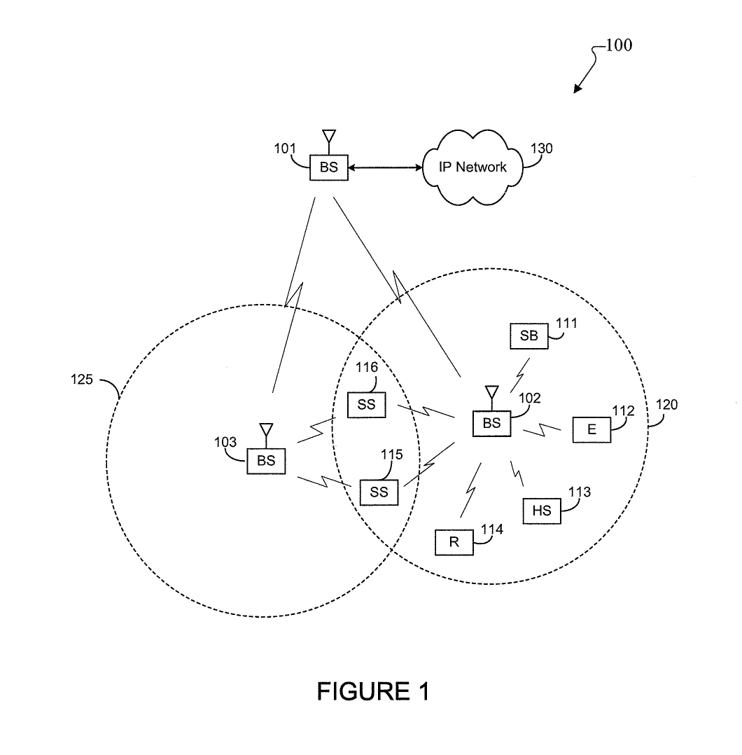

FIGS. 1 through 11, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged amplifier of a wireless network system.

In certain embodiments of the present disclosure, a distributed amplifier is integrated with an envelope tracking path to provide an envelope tracked drain voltage simultaneously to all transistors of the distributed amplifier. In certain embodiments, a distributed amplifier is integrated with a polar transmitter architecture to provide a phase modulated constant amplitude RF drive to the first transistor of the distributed amplifier and simultaneously to provide an envelope tracked drain voltage to all transistors.

Due to the industry changes requiring support for concurrent multi-band operation, global roaming, and Long-Term Evolution (LTE) carrier aggregation, future power amplifier designs will need to support both high efficiency and wideband or concurrent multi-band operation. To support these demands, it is necessary to find a power amplifier architecture that can operate efficiently and have bandwidth potentially in excess of an octave or more. Distributed power amplifier architectures have wide bandwidth operation, but may not be very efficient. The efficiency of the distributed amplifier can be improved using envelope tracking or polar techniques without sacrificing wide bandwidth. The present disclosure describes multiple embodiments of envelope tracking and polar distributed amplifiers implemented either using complete analog architectures or a combination of analog and digital architectures. Also included in the present disclosure is the concept of envelope tracking and polar non-uniform distributed amplifier architectures. These techniques offer significant potential to meeting the daunting efficiency and bandwidth demands of the next generation of wireless power amplifier for both the mobile and infrastructure equipment.

A frequent trade-off in wireless system radio frequency power amplifier design is often between the power added efficiency of the amplifier circuit and its bandwidth. In order to adequately match the output impedance of the power amplifier circuit to that of the load and source impedances, resonant matching networks must be used to transform the impedances. These matching networks are frequently constructed of lumped element components, transmission lines sections, a transformer, or some combination of these.

Typically a power transistor of a power amplifier circuit attains its peak power added efficiency, gain, and output power when terminated with a relatively narrow range of complex source and load impedances and this optimum matching impedance is normally not constant across a wide frequency range. Hence, resonant matching circuits, particularly one or two section matching networks, are often only optimum for power added efficiency over a relatively narrow range of frequencies that is often less than a 5% bandwidth relative to the carrier frequency.

To achieve wider bandwidth operation, multiple matching network sections can be used. Using this technique it is possible to maintain near optimum impedance matching conditions over a larger bandwidth. Since there is a finite insertion loss incurred by each section of the matching network, the tradeoff for wider band operation is often lower gain and lower efficiency.

In modern wireless systems there is increasing pressure to improve both the power added efficiency and the bandwidth of the power amplifiers in the systems. Demand for higher power added efficiency is driven by the need to extended battery life in mobile devices and by the need for reduced capital cost and operating cost in infrastructure equipment. Power amplifier efficiency that is low causes higher electricity usage resulting in higher operating cost. This forces the use of more extensive and expensive cooling features in the equipment thus increasing capital equipment cost.

Wide bandwidth demands on power amplifier circuits in modern wireless systems are being driven by multi-band requirements for support of roaming in mobile devices. LTE carrier aggregation requirements will also drive the need for wideband operation in mobile devices. In infrastructure equipment, wireless operators are increasing operating services_concurrently in multiple bands to support legacy air interface while overlaying new spectrum to support newer air interfaces such as LTE. Demand for carrier aggregation capability in infrastructure equipment also continues to increase the need for concurrent multi-band operation of transmitters.

An issue affecting power amplifier efficiency is the peak-to-average ratio of the transmitted waveform. At peak operating power with a continuous waveform (CW) signal, a power amplifier may operate with high efficiency. However, as the output power is reduced, the efficiency drops significantly. Since most waveforms used in modern wireless communication systems (Code Division Multiple Access (CDMA), Wideband Code Division Multiple Access (WCDMA), Worldwide Interoperability for Microwave Access (WiMax), LTE, High Speed Packet Access (HSPA), and the like) have widely fluctuating amplitudes, the average transmitted power must be set with some back-off from the peak to avoid non-linear distortion at the waveform peaks. The amount of back-off required is closely related to the peak-to-average ratio of the transmitted waveform.

FIG. 1 illustrates a wireless network 100 according to one embodiment of the present disclosure. The embodiment of wireless network 100 illustrated in FIG. 1 is for illustration only. Other embodiments of wireless network 100 could be used without departing from the scope of this disclosure.

The wireless network 100 includes eNodeB (eNB) 101, eNB 102, and eNB 103. The eNB 101 communicates with eNB 102 and eNB 103. The eNB 101 also communicates with Internet protocol (IP) network 130, such as the Internet, a proprietary IP network, or other data network.

Depending on the network type, other well-known terms may be used instead of “eNodeB,” such as “base station” or “access point”. For the sake of convenience, the term “eNodeB” shall be used herein to refer to the network infrastructure components that provide wireless access to remote terminals. In addition, the term “user equipment” or “UE” is used herein to designate any remote wireless equipment that wirelessly accesses an eNB and that can be used by a consumer to access services via the wireless communications network, whether the UE is a mobile device (e.g., cell phone) or is normally considered a stationary device (e.g., desktop personal computer, vending machine, etc.). Other well know terms for the remote terminals include “mobile stations” (MS) and “subscriber stations” (SS), “remote terminal” (RT), “wireless terminal” (WT), and the like.

The eNB 102 provides wireless broadband access to network 130 to a first plurality of user equipments (UEs) within coverage area 120 of eNB 102. The first plurality of UEs includes UE ill, which may be located in a small business; UE 112, which may be located in an enterprise; UE 113, which may be located in a WiFi hotspot; UE 114, which may be located in a first residence; UE 115, which may be located in a second residence; and UE 116, which may be a mobile device, such as a cell phone, a wireless laptop, a wireless PDA, or the like. UEs 111-116 may be any wireless communication device, such as, but not limited to, a mobile phone, mobile PDA and any mobile station (MS).

The eNB 103 provides wireless broadband access to a second plurality of UEs within coverage area 125 of eNB 103. The second plurality of UEs includes UE 115 and UE 116. In some embodiments, one or more of eNBs 101-103 may communicate with each other and with UEs 111-116 using 5G, LTE, LTE-A, or WiMAX techniques including techniques for envelope tracking with distributed amplifiers as described in embodiments of the present disclosure.

Dotted lines show the approximate extents of coverage areas 120 and 125, which are shown as approximately circular for the purposes of illustration and explanation only. It should be clearly understood that the coverage areas associated with base stations, for example, coverage areas 120 and 125, may have other shapes, including irregular shapes, depending upon the configuration of the base stations and variations in the radio environment associated with natural and man-made obstructions.

Although FIG. 1 depicts one example of a wireless network 100, various changes may be made to FIG. 1. For example, another type of data network, such as a wired network, may be substituted for wireless network 100. In a wired network, network terminals may replace eNBs 101-103 and UEs 111-116. Wired connections may replace the wireless connections depicted in FIG. 1.

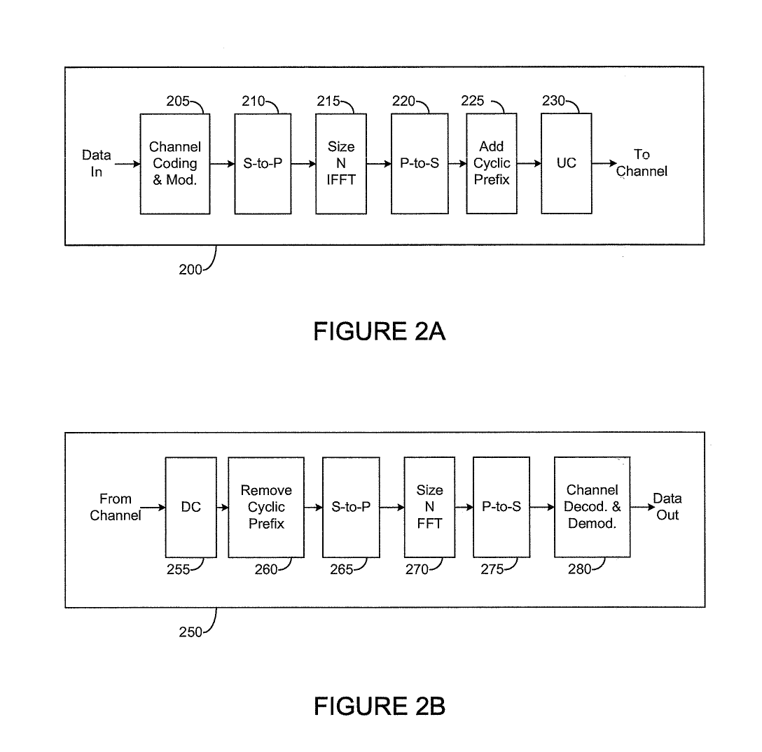

FIG. 2A is a high-level diagram of a wireless transmit path. FIG. 2B is a high-level diagram of a wireless receive path. In FIGS. 2A and 2B, the transmit path 200 may be implemented, e.g., in eNB 102 and the receive path 250 may be implemented, e.g., in a UE, such as UE 116 of FIG. 1. It will be understood, however, that the receive path 250 could be implemented in an eNB (e.g. eNB 102 of FIG. 1) and the transmit path 200 could be implemented in a UE. In certain embodiments, transmit path 200 and receive path 250 are configured to perform methods for envelope tracking distributed amplifiers as described in embodiments of the present disclosure.

Transmit path 200 comprises channel coding and modulation block 205, serial-to-parallel (S-to-P) block 210, Size N Inverse Fast Fourier Transform (IFFT) block 215, parallel-to-serial (P-to-S) block 220, add cyclic prefix block 225, up-converter (UC) 230. Receive path 250 comprises down-converter (DC) 255, remove cyclic prefix block 260, serial-to-parallel (S-to-P) block 265, Size N Fast Fourier Transform (FFT) block 270, parallel-to-serial (P-to-S) block 275, channel decoding and demodulation block 280.

At least some of the components in FIGS. 2A and 2B may be implemented in software while other components may be implemented by configurable hardware (e.g., a processor) or a mixture of software and configurable hardware. In particular, it is noted that the FFT blocks and the IFFT blocks described in this disclosure document may be implemented as configurable software algorithms, where the value of Size N may be modified according to the implementation.

Furthermore, although this disclosure is directed to an embodiment that implements the Fast Fourier Transform and the Inverse Fast Fourier Transform, this is by way of illustration only and should not be construed to limit the scope of the disclosure. It will be appreciated that in an alternate embodiment of the disclosure, the Fast Fourier Transform functions and the Inverse Fast Fourier Transform functions may easily be replaced by Discrete Fourier Transform (DFT) functions and Inverse Discrete Fourier Transform (IDFT) functions, respectively. It will be appreciated that for DFT and IDFT functions, the value of the N variable may be any integer number (i.e., 1, 2, 3, 4, etc.), while for FFT and IFFT functions, the value of the N variable may be any integer number that is a power of two (i.e., 1, 2, 4, 8, 16, etc.).

In transmit path 200, channel coding and modulation block 205 receives a set of information bits, applies coding (e.g., LDPC coding) and modulates (e.g., Quadrature Phase Shift Keying (QPSK) or Quadrature Amplitude Modulation (QAM)) the input bits to produce a sequence of frequency-domain modulation symbols. Serial-to-parallel block 210 converts (i.e., de-multiplexes) the serial modulated symbols to parallel data to produce N parallel symbol streams where N is the IFFT/FFT size used in eNB 102 and UE 116. Size N IFFT block 215 then performs an IFFT operation on the N parallel symbol streams to produce time-domain output signals. Parallel-to-serial block 220 converts (i.e., multiplexes) the parallel time-domain output symbols from Size N IFFT block 215 to produce a serial time-domain signal. Add cyclic prefix block 225 then inserts a cyclic prefix to the time-domain signal. Finally, up-converter 230 modulates (i.e., up-converts) the output of add cyclic prefix block 225 to RF frequency for transmission via a wireless channel. The signal may also be filtered at baseband before conversion to RF frequency.

The transmitted RF signal arrives at UE 116 after passing through the wireless channel and reverse operations to those at eNB 102 are performed. Down-converter 255 down-converts the received signal to baseband frequency and remove cyclic prefix block 260 removes the cyclic prefix to produce the serial time-domain baseband signal. Serial-to-parallel block 265 converts the time-domain baseband signal to parallel time domain signals. Size N FFT block 270 then performs an FFT algorithm to produce N parallel frequency-domain signals. Parallel-to-serial block 275 converts the parallel frequency-domain signals to a sequence of modulated data symbols. Channel decoding and demodulation block 280 demodulates and then decodes the modulated symbols to recover the original input data stream.

Each of eNBs 101-103 may implement a transmit path that is analogous to transmitting in the downlink to UEs 111-116 and may implement a receive path that is analogous to receiving in the uplink from UEs 111-116. Similarly, each one of UEs 111-116 may implement a transmit path corresponding to the architecture for transmitting in the uplink to eNBs 101-103 and may implement a receive path corresponding to the architecture for receiving in the downlink from eNBs 101-103.

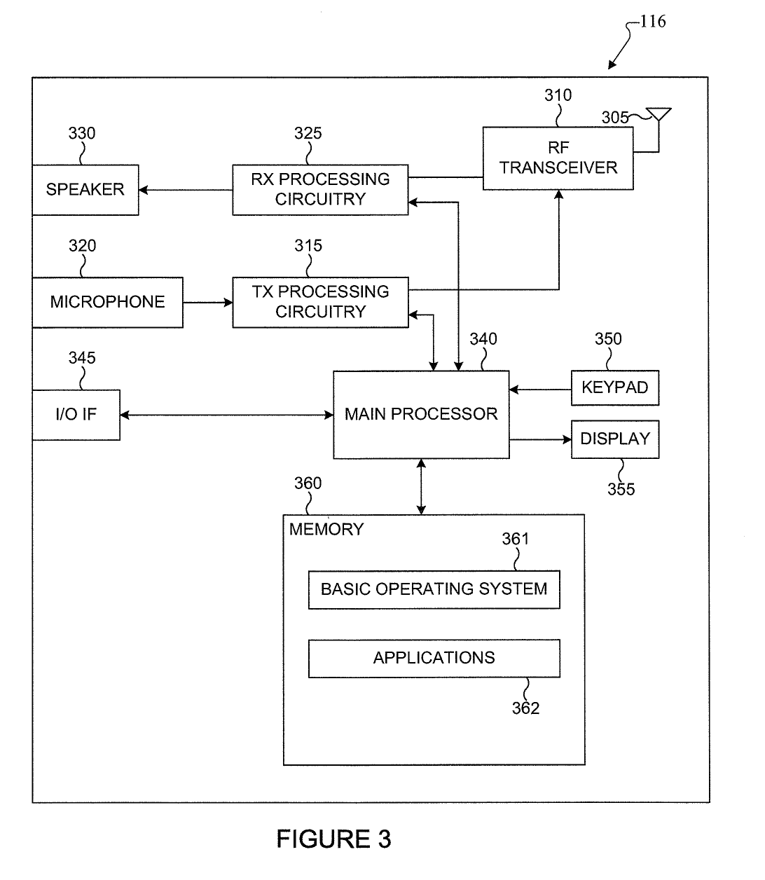

FIG. 3 illustrates a mobile station according to embodiments of the present disclosure. The embodiment of the mobile station, such as UE 116, illustrated in FIG. 3 is for illustration only. Other embodiments of the wireless mobile station could be used without departing from the scope of this disclosure.

UE 116 comprises antenna 305, radio frequency (RF) transceiver 310, transmit (TX) processing circuitry 315, microphone 320, and receive (RX) processing circuitry 325. Although shown as a single antenna, antenna 305 can include multiple antennas. SS 116 also comprises speaker 330, main processor 340, input/output (I/O) interface (IF) 345, keypad 350, display 355, and memory 360. Memory 360 further comprises basic operating system (OS) program 361 and a plurality of applications 362. The plurality of applications can include one or more of resource mapping tables (Tables 1-10 described in further detail herein below).

Radio frequency (RF) transceiver 310 receives from antenna 305 an incoming RF signal transmitted by a base station of wireless network 100. Radio frequency (RF) transceiver 310 down-converts the incoming RF signal to produce an intermediate frequency (IF) or a baseband signal. The IF or baseband signal is sent to receiver (RX) processing circuitry 325 that produces a processed baseband signal by filtering, decoding, and/or digitizing the baseband or IF signal. Receiver (RX) processing circuitry 325 transmits the processed baseband signal to speaker 330 (i.e., voice data) or to main processor 340 for further processing (e.g., web browsing).

Transmitter (TX) processing circuitry 315 receives analog or digital voice data from microphone 320 or other outgoing baseband data (e.g., web data, e-mail, interactive video game data) from main processor 340. Transmitter (TX) processing circuitry 315 encodes, multiplexes, and/or digitizes the outgoing baseband data to produce a processed baseband or IF signal. Radio frequency (RF) transceiver 310 receives the outgoing processed baseband or IF signal from transmitter (TX) processing circuitry 315. Radio frequency (RF) transceiver 310 up-converts the baseband or IF signal to a radio frequency (RF) signal that is transmitted via antenna 305.

In certain embodiments, main processor 340 is a microprocessor or microcontroller. Memory 360 is coupled to main processor 340. According to some embodiments of the present disclosure, part of memory 360 comprises a random access memory (RAM) and another part of memory 360 comprises a Flash memory, which acts as a read-only memory (ROM).

Main processor 340 executes basic operating system (OS) program 361 stored in memory 360 in order to control the overall operation of wireless subscriber station 116. In one such operation, main processor 340 controls the reception of forward channel signals and the transmission of reverse channel signals by radio frequency (RF) transceiver 310, receiver (RX) processing circuitry 325, and transmitter (TX) processing circuitry 315, in accordance with well-known principles and including techniques for envelope tracking with distributed amplifiers as described in embodiments of the present disclosure.

Main processor 340 is capable of executing other processes and programs resident in memory 360. Main processor 340 can move data into or out of memory 360, as required by an executing process. In some embodiments, the main processor 340 is configured to execute a plurality of applications 362, such as applications for CoMP communications and MU-MIMO communications. The main processor 340 can operate the plurality of applications 362 based on OS program 361 or in response to a signal received from ES 102. Main processor 340 is also coupled to I/O interface 345. I/O interface 345 provides subscriber station 116 with the ability to connect to other devices such as laptop computers and handheld computers. I/O interface 345 is the communication path between these accessories and main controller 340.

Main processor 340 is also coupled to keypad 350 and display unit 355. The operator of subscriber station 116 uses keypad 350 to enter data into subscriber station 116. Display 355 may be a liquid crystal display capable of rendering text and/or at least limited graphics from web sites. Alternate embodiments may use other types of displays.

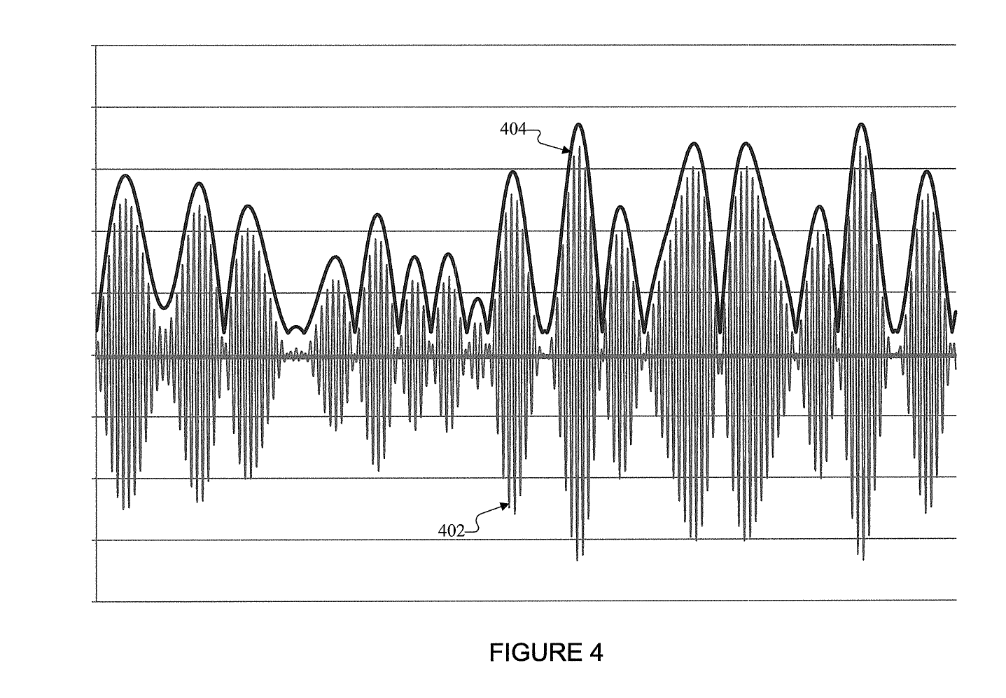

FIG. 4 illustrates envelope tracking of a waveform according to embodiments of the present disclosure. Envelope tracking is a technique for achieving improved efficiency in power amplifier. As depicted, waveform 404 is the drain or collector voltage of the final active device, and in some cases the prior driver stage(s). Waveform 404 varies roughly proportionally to the instantaneous waveform envelope level of a modulated radio frequency (RF) waveform 402. Using this technique, less power is dissipated in a power transistor when the instantaneous envelope power is below the peak operating power of the transistor. Envelope tracking techniques are being broadly deployed in infrastructure transmitters to reduce the operating cost and capital cost of the equipment through efficiency improvements. The efficiency of the power amplifier is overwhelmingly the largest single factor in the base station power consumption and the base station thermal design, therefore the efficiency improvement realized using envelope tracking is clearly an advantage. Likewise in the wireless mobile devices, there is much industry activity to deploy envelope tracking power amplifiers to enhance the battery life while still supporting high order modulation waveforms.

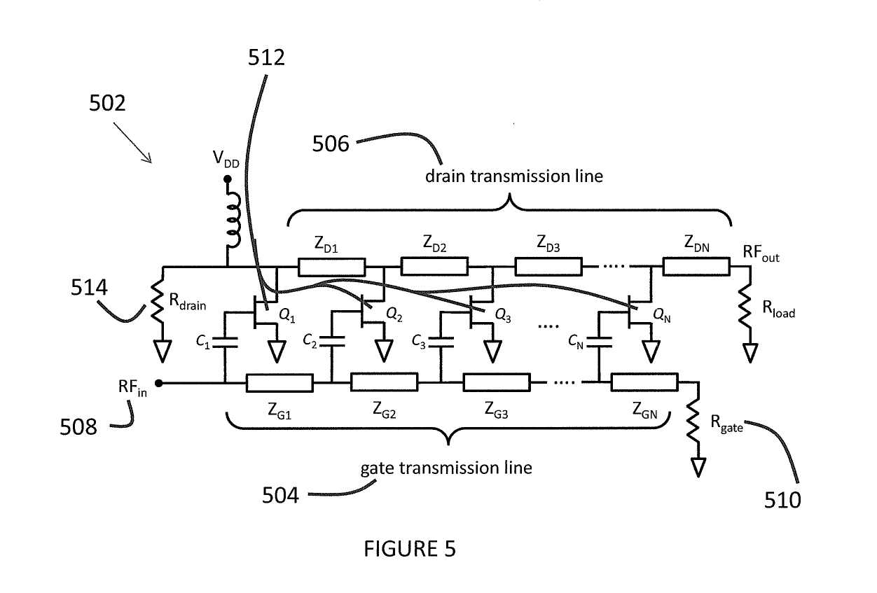

FIG. 5 illustrates a distributed amplifier according to an exemplary embodiment of the disclosure. Although the greater focus within the wireless industry has been on power amplifier improvements, with greater demands for wideband and concurrent multi-band operation in wireless mobile devices and infrastructure equipment, there is increasing attention toward widening the operating frequency range of the transmitter power amplifiers. For applications such as military electronic warfare systems and optical networks, an amplifier architecture used to achieve a greater gain-bandwidth product is called the distributed amplifier or traveling wave amplifier. In the distributed amplifier architecture, multiple transistor devices are configured in a parallel array effectively with one transmission line to distribute the input signal to the gate or base of each transistor and another artificial transmission line used to coherently combine the amplified drain or collector signals of all of the devices.

By combining the input and output networks of the transistors using transmission line, it is possible to absorb the input and output capacitance of the active devices as part of an artificial transmission line thereby providing a broadband response. The transmission lines are coupled by the transconductances of the transistor stages to provide a relatively flat, low-pass response across a wide bandwidth. This is in contrast to a cascade amplifier architecture in which the device input and output capacitance is transformed using a resonant circuit which has a natural narrow bandpass response. A distributed amplifier can often provide in excess of a decade of instantaneous bandwidth. However, the power added efficiency of the distributed amplifier does not often compare well to a single or cascaded common-source circuit.

The amplifier architecture can be implemented either using field effect transistors (FET) or bipolar junction transistors (BJT). Therefore in further descriptions of the circuit any reference to the transistor drain refers to both the drain of an FET or the collector of a BJT. Likewise, any reference to the transistor gate refers to both the gate of an FET or the base of a BJT.

As in FIG. 5, a distributed amplifier 502 includes two transmission lines. The first transmission line is gate line 504, also referred to as gate transmission line. The second transmission line is drain line 506, also referred to as drain transmission line. Waveform 508, also referred to as signal and RFᵢₙ, is an RF signal that is applied to gate line 504. Waveform 508 may correspond to waveform 402 of FIG. 4. The drain voltage, V_{DD}, may correspond to waveform 404 of FIG. 4. Waveform 508 propagates down the gate line 504 and is terminated by resistive load 510 (also referred to as R_{gate}) to minimize reflection of waveform 508. As signal 508 propagates down gate transmission line 504, each transistor 512 amplifies the signal 508 through its transconductance onto drain transmission line 506. The signal from each transistor 512 propagated down the drain transmission line 506 add coherently in a forward direction under the condition that phase velocities on the gate line 504 and drain line 506 are identical for all transistors 512. The signals from the transistor drains on the drain transmission line 506 traveling in the reverse direction are out of phase and will therefore cancel. Any residual signal in the reverse direction that is not cancelled will be absorbed by the drain transmission line termination 514, also referred to as R_{drain}.

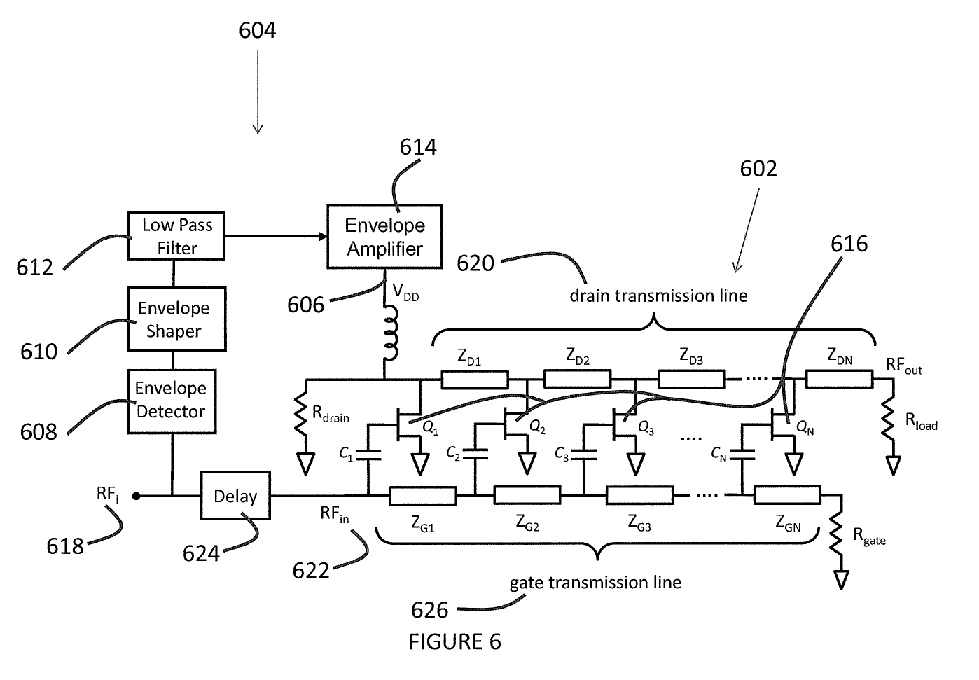

FIG. 6 illustrates a distributed amplifier 602 configured with an envelope tracking path 604 according to an exemplary embodiment of the disclosure. Envelope tracking path 604 is attached to a common drain or collector line 606 in order to simultaneously achieve higher efficiency and wide bandwidth operation. As shown in FIG. 6, this is accomplished by first detecting a waveform envelope of the input signal 618 (also referred to as RFᵢ) via envelope detector 608 and then appropriately shaping the waveform via envelope shaper 610 and filtering the waveform via low pass filter 612 to achieve optimum out-of-band noise, adjacent channel power ratio (ACPR), and efficiency. The resulting waveform from low pass filter 612 is then amplified using envelope amplifier 614, also referred to as EA 614. EA 614 is effectively a high efficiency, high bandwidth driver that provides the drain or collector of the distributed amplifier 602 transistors 616 with a voltage that instantaneously tracks the envelope level of the input signal 618 with sufficient current source capability matched to the requirements of the distributed amplifier transistors 616. Since all transistors 616 within the distributed amplifier 602 receive a drain or collector bias from a common current supply, a single EA 614 is able to modulate this voltage to all of the transistors 616 simultaneously. In certain descriptions of distributed amplifiers, the drain voltage, V_{DD}, is a constant DC voltage.

Since the drain voltage at line 606 is distributed to the amplifier transistors 616 across drain transmission line 620, some expected delay of several carrier cycles from the first transistor (Q₁) in the array of transistors 616 to the last (Q_{N}) occurs. Yet since the bandwidth of the envelope is expected to be a fraction of the carrier frequency, several carrier cycles of delay should not significantly impact the ACLR or efficiency of the distributed amplifier 602.

Input signal 618 is delayed via delay 624 before being applied as waveform 622 (also referred to as RFᵢₙ) to distributed amplifier 602. Delay 624 allows for the output of envelope amplifier 614 to be properly synchronized with waveform 622.

In the envelope tracking distributed amplifier of FIG. 6, the array of transistors 616 comprises a plurality of transistors configured in a parallel configuration. The minimum number of transistor stages is two, but larger arrays are also included within the scope of the present disclosure. In general, fewer number of transistor stages will result in higher gain and power added efficiency, but lower bandwidth. Conversely, a greater number of transistor stages will result in lower gain and power added efficiency, but higher bandwidth. Distributed amplifiers may have greater than a decade of bandwidth using ten transistor stages.

In certain embodiments, all the transistors 616 are scaled identically and the impedance of transmission lines 620 and 626 is designed to be constant across the entire length of transmission lines 620 and 626. This is considered a uniform envelope tracking distributed amplifier. Due to a natural taper in a signal's amplitude as it propagates across the gate transmission line 626, subsequent transistor stages receive decreasing levels of gate drive. If the optimum load impedance of the final stage based on its drive level is designed for appropriate matching to a typical 50 ohm resistive load, then use of the same drain transmission line impedance for the initial transistor stages which receive high drive level will result in sub-optimal gain and power added efficiency for the initial stages.

A technique to optimize the load characteristics seen by each transistor stage involves tapering of the characteristic impedances of sections of drain transmission line 620 in order to maintain an optimum load presented to each transistor stage. In addition, another technique used is to combine drain transmission line impedance taper with transistor device sizing such that some transistor stages have larger periphery and some have smaller periphery scaled to provide optimum gain and efficiency performance into reduced transmission line impedances. This architecture is known as a non-uniform distributed amplifier. In certain embodiments of this disclosure, the envelope amplifier is combined with a non-uniform distributed amplifier architecture to further enhance the gain and power added efficiency of the envelope track distributed amplifier implementation. The envelope tracking non-uniform distributed amplifier architecture is also illustrated in FIG. 6, but in this case sections Z_{D1} through Z_{DN} of drain transmission line 620 are not of equal characteristic impedance. Other techniques may also be implemented within the non-uniform envelope tracking distributed amplifier such as tapering of the series gate capacitor values for subsequent transistor stages in order to equalize the RF drive voltage provided to the gates of transistors 616.

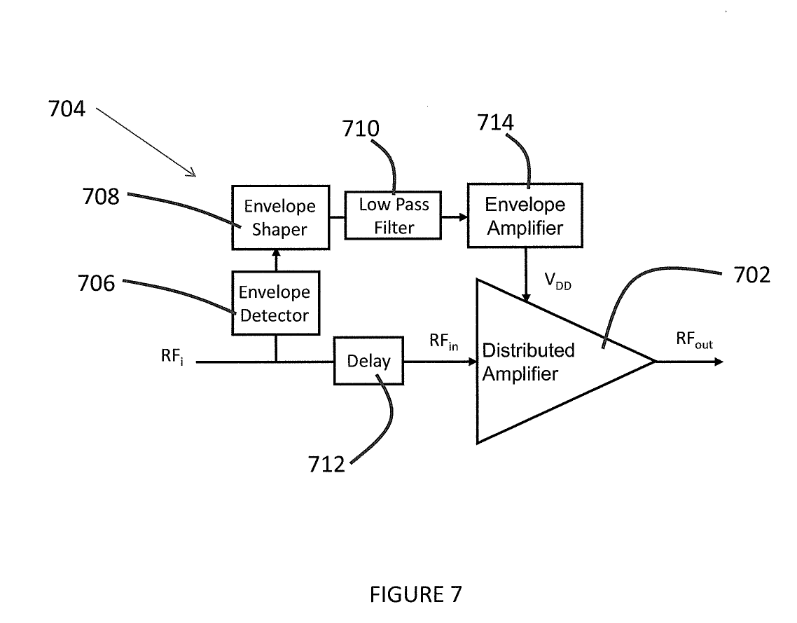

FIG. 7 illustrates a distributed amplifier 702 configured with an analog envelope tracking architecture according to an exemplary embodiment of the disclosure. The envelope tracking path 704 of the analog envelope tracking architecture is implemented entirely using analog circuit blocks as illustrated in FIG. 7 in which the envelope detector 706, envelope shaper 708, low pass filter 710, delay element 712, and envelope amplifier 714 are constructed with analog circuits, which may be programmable analog circuits. Use of the analog envelope tracking architecture of the embodiment of FIG. 7 may be advantageous in MSs so that amplification of the waveform may be done without modification to a baseband processor of the MS. In this architecture either the uniform distributed amplifier or the non-uniform distributed amplifier can be used. The non-uniform distributed amplifier used on the polar architecture may provide better gain and efficiency.

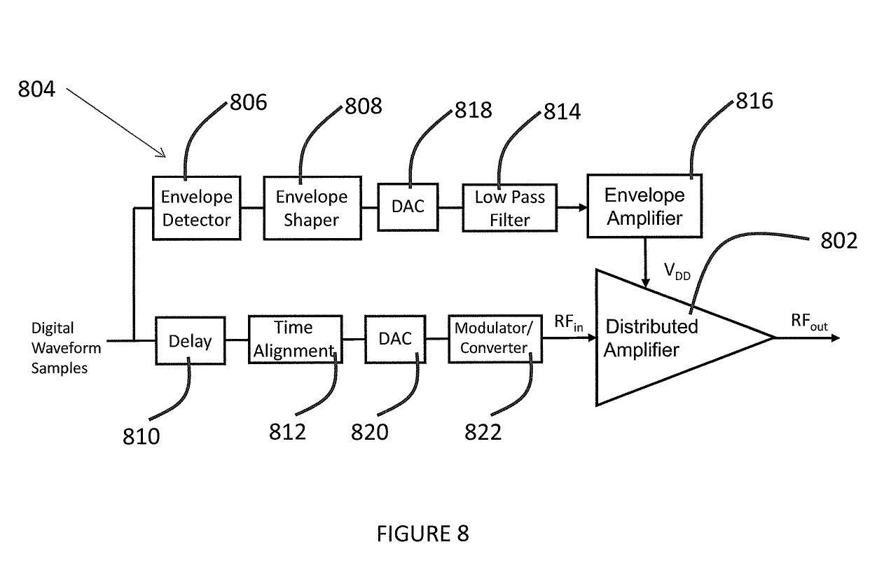

FIG. 8 illustrates a distributed amplifier 802 configured with a digital envelope tracking architecture according to an exemplary embodiment of the disclosure. The envelope tracking path 804 of digital envelope tracking architecture can be implemented using a combination of digital and analog blocks as illustrated in FIG. 8. In this illustration the envelope detector 806, envelope shaper 808, delay element 810, and time alignment 812 are implemented using digital circuits, such as a baseband processor or a digital signal processor, whereas the low pass filter 814 and envelope amplifier 816 remain predominately analog circuits. Digital to analog converters (DACs) 818 and 820 are used to convert between the digital circuits and analog circuits. Modulator/converter 822 converts the output from DAC 820 into a modulated signal to be amplified by distributed amplifier 802. Use of the digital envelope tracking architecture of the embodiment of FIG. 8 may be advantageous in BSs to provide greater accuracy and flexibility in the envelope detector and shaping and time alignment in order to optimize power amplifier efficiency and modulation accuracy. In this architecture, the digital functions could be implemented either by a digital signal processor, digital logic circuits, or some combination of these. In this architecture either the uniform distributed amplifier or the non-uniform distributed amplifier can be used. The non-uniform distributed amplifier used on the polar architecture may provide better gain and efficiency.

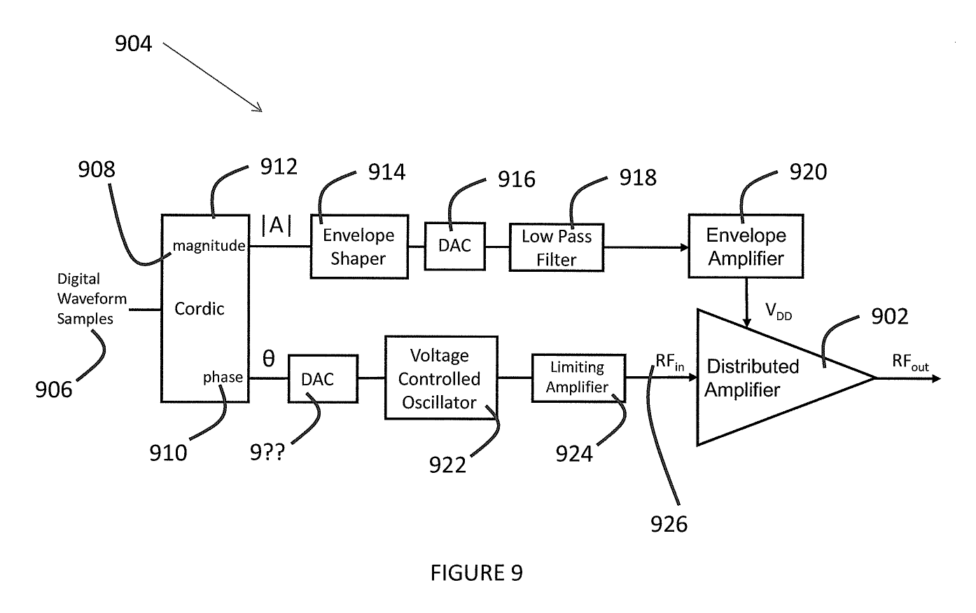

FIG. 9 illustrates a distributed amplifier configured with a digital polar architecture according to an exemplary embodiment of the disclosure. In certain embodiments, a distributed amplifier 902 is integrated with a polar amplifier architecture 904. An alternate reference to the polar architecture is envelope elimination and restoration. In this architecture the digital signal in the form of digital waveform samples 906 is split into a magnitude component 908 and a phase component. This is commonly done using a Coordinate Rotation Digital Computer (Cordic) function in digital signal process block 912. Magnitude component 908, also referred to as magnitude element 908 and |A|, is used to drive the envelope tracking path comprising an envelope shaper 914, digital to analog converter 916, low pass filter 918, and envelope amplifier 920. Phase component 910, also referred to as phase signal 910 and Θ, is converted from digital to analog by DAC 928 and is used to phase modulate an oscillator, such as voltage controlled oscillator 922 that generates the carrier tone. The carrier tone is driven into a saturated or limiting amplifier 924 to produce a constant amplitude, phase modulated RF carrier that is used as the input to distributed amplifier 902. This allows distributed amplifier 902 to be driven at its peak efficiency over the full waveform dynamic range. This phase modulated waveform 926, also referred to as RFᵢₙ, then receives amplitude modulation through the envelope tracking drain voltage applied by EA 920 to distributed amplifier 902. In this architecture either the uniform distributed amplifier or the non-uniform distributed amplifier can be used. The non-uniform distributed amplifier used on the polar architecture may provide better gain and efficiency.

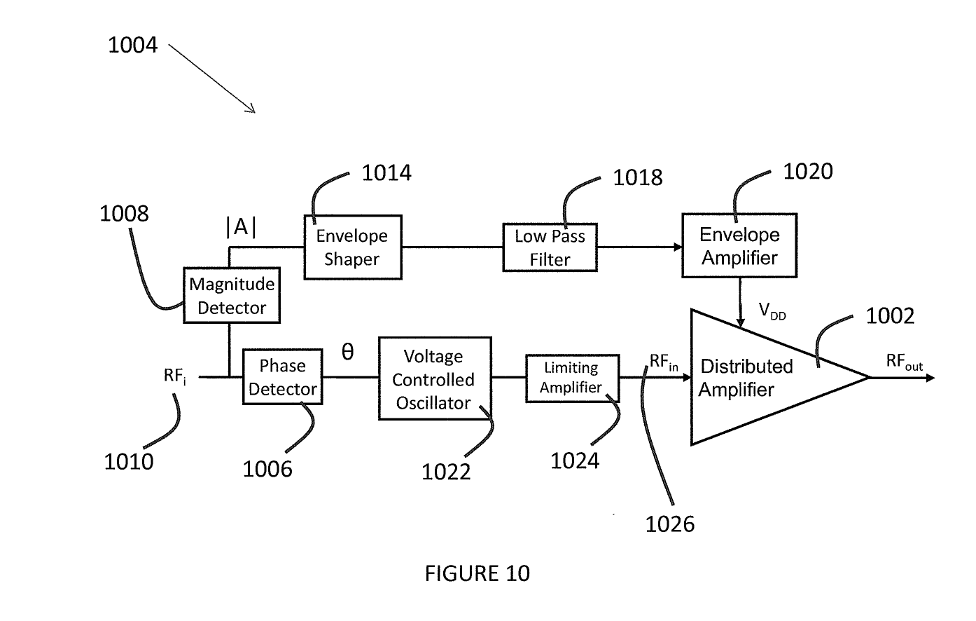

FIG. 10 illustrates a distributed amplifier configured with an analog polar architecture according to an exemplary embodiment of the disclosure. In this embodiment, a distributed amplifier 1002 is integrated with a polar drive architecture 1004. In this architecture the analog signal in the form of RFᵢ 1010 is split into a magnitude component via magnitude detector 1008 and a phase component via phase detector 1006. The magnitude component, also referred to as |A|, and is used to drive the envelope tracking path comprising an envelope shaper 1014, low pass filter 1018, and envelope amplifier 1020. The phase component, also referred to as Θ, is used to phase modulate an oscillator, such as voltage controlled oscillator 1022 that generates the carrier tone. The carrier tone is driven into a saturated or limiting amplifier 1024 to produce a constant amplitude, phase modulated RF carrier that is used as the input to distributed amplifier 1002. This allows distributed amplifier 1002 to be driven at its peak efficiency over the full waveform dynamic range. This phase modulated waveform 1026, also referred to as RFᵢₙ, then receives amplitude modulation through the envelope tracking drain voltage applied by EA 1020 to distributed amplifier 1002. In this architecture either the uniform distributed amplifier or the non-uniform distributed amplifier can be used. The non-uniform distributed amplifier used on the polar architecture may provide better gain and efficiency.

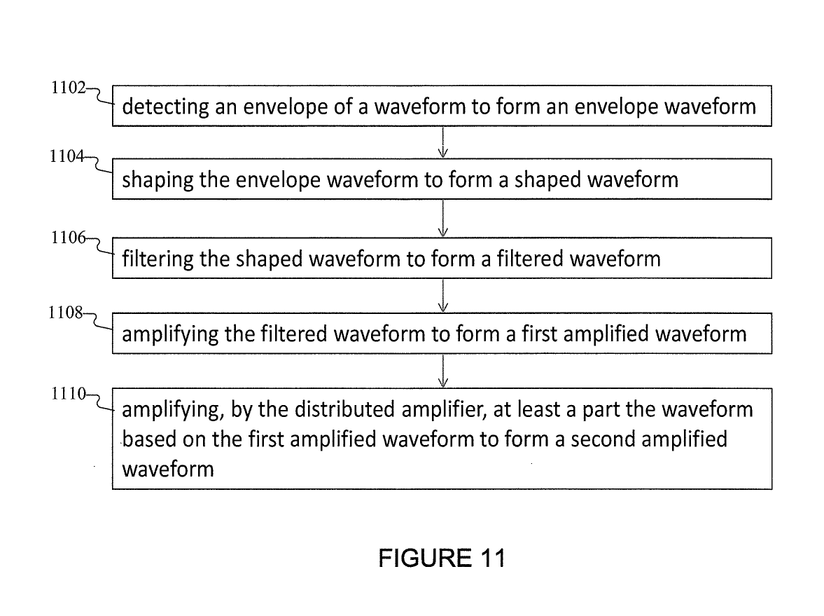

FIG. 11 is a flow diagram illustrating amplification of a waveform in a wireless network according to an exemplary embodiment of the disclosure. The amplification uses an envelope amplifier to drive a distributed amplifier, as shown in FIG. 6. At 1102, an envelope of a waveform is detected to form an envelope waveform. The waveform can be an analog signal or a digital signal in the form of digital waveform samples and is an embodiment of signal 402 of FIG. 4. The envelope of the waveform may correspond to a full wave rectification of the waveform with additional smoothing, such as via a capacitive element or the like.

The envelope waveform may be an output of a digital or analog envelope detector that performs the detection of the envelope.

At 1104, the envelope waveform is shaped to form a shaped waveform. The shaping is based on one or more characteristics of a distributed amplifier to which a second amplified waveform, which is based on the shaped waveform, will be applied. The one or more characteristics of the distributed amplifier for which the envelope waveform is shaped includes a minimum drain voltage of the distributed amplifier, a linearity of the distributed amplifier, a gain variation behavior of the distributed amplifier over the dynamic range, a required Error Vector Magnitude (EVM) and Adjacent Channel Power Ratio (ACPR) for the applicable air interface standard, and the like. The shaped waveform may be an output of a digital or analog envelope shaper that performs the detection of the envelope.

At 1106, the shaped waveform is filtered to form a filtered waveform. The filtering removes noise or distortion introduced by one or more other components or steps, such as detecting the envelope and converting the shaped waveform from digital to analog. For example, when using an analog envelope tracking architecture as in FIG. 7, envelope detector 406 may introduce wideband noise and distortion that are filtered out by low pass filter 410. As another example, when using a digital envelope tracking architecture as in FIG. 5, the digital to analog converter 406 may introduce wideband image products that are filtered out by low pass filter 410. Hence, the filtering may be based on the other components in the system and may be based on the type of system. The shaped waveform may be an input to a filter and the filtered waveform may be an output of the filter that performs the filtering.

At 1108, the filtered waveform is amplified to form a first amplified waveform. This first amplification amplifies the signal so as to drive a distributed amplifier. The filtered waveform may be an input to an envelope amplifier and the first amplified waveform may be an output of the envelope amplifier.

At 1110, at least part of the waveform is amplified based on the first amplified waveform to form a second amplified waveform. This second amplification amplifies the signal to be ready for transmission via an antenna. The second amplification modifies each of a plurality of transistors of the distributed amplifier with the second amplified waveform. The at least part of the waveform and the first amplified waveform may be inputs to a distributed amplifier and the second amplified waveform may be an output of the distributed amplifier. The second amplified waveform may be transmitted and may be an input to an antenna.

An alternative embodiment of the method of FIG. 11 may include processing the initial waveform to form a magnitude waveform and a phase waveform. In this embodiment, the magnitude waveform may be used as an envelope waveform, as described above, and the phase waveform may be the part of the waveform amplified by the distributed amplifier, as described above.

In embodiments of the present disclosure, the envelope tracking distributed amplifier can be implemented using Gallium Nitride (GaN), Gallium Arsenide (GaAs), Silicon-Germanium SiGe, Indium Gallium Phosphide (InGaP), Laterally Diffused Metal Oxide Semiconductor (LDMOS), or even Complementary metal-oxide-semiconductor (CMOS) transistor technology, although the highest power added efficiency and widest bandwidth will likely be achieved using GaN transistors due to the higher breakdown voltage and electron mobility of this technology. Initial estimates indicate implementation of an envelope tracking distributed amplifier or polar distributed amplifier using GaN device technology in a non-uniform topology would possibly provide power added efficiencies that are greater than 30 to 35% for a modulated waveform having a PAR of up to 6 dB operating over several octaves of bandwidth.

While tuned single stage envelope tracking amplifiers have been demonstrated to achieve a PAE of up to 50%, this is only possible over a relatively narrow tuned bandwidth of about 5%. Therefore while the envelope tracking distributed amplifier presented in this disclosure will likely not match the PAE of the tuned envelope tracking amplifier, it can provide substantially greater gain-bandwidth product to support wideband or concurrent multi-band wireless applications while still operating with sufficient power added efficiency to support required battery life and operating expense requirements of wireless networks.

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. A method to amplify a waveform in a wireless network, the method comprising:
detecting an envelope of a waveform to form an envelope waveform;
shaping the envelope waveform to form a shaped waveform, the shaping based on one or more characteristics of a distributed amplifier;
filtering the shaped waveform to form a filtered waveform;
amplifying the filtered waveform to form a first amplified waveform; and
amplifying, by the distributed amplifier, at least a part the waveform based on the first amplified waveform to form a second amplified waveform.

2. The method of claim 1, further comprising:
transmitting the second amplified waveform.

3. The method of claim 1, wherein the filtering removes noise introduced by one or more of the detecting and converting the shaped waveform from digital to analog.

4. The method of claim 1, wherein a first characteristic of the one or more characteristics is a minimum voltage of the distributed amplifier.

5. The method of claim 1, wherein a second characteristic of the one or more characteristics is a linearity of the distributed amplifier.

6. The method of claim 1, wherein the distributed amplifier comprises one of a plurality of field effect transistors and a plurality of bipolar junction transistors.

7. The method of claim 1, further comprising:
modifying each of a plurality of transistors of the distributed amplifier with the second amplified waveform.

8. The method of claim 1, further comprising:
processing the waveform to form a magnitude waveform and a phase waveform;
using the magnitude waveform as the envelope waveform;
using the phase waveform as the part of the waveform amplified by the distributed amplifier.

9. A mobile station (MS) configured to amplify a waveform, the MS comprising:
a detector configured to detect an envelope of the waveform to form an envelope waveform;
a shaper configured to shape the envelope waveform to form a shaped waveform based on one or more characteristics of a distributed amplifier;
a filter configured to filter the shaped waveform to form a filtered waveform;
an envelope amplifier configured to amplify the filtered waveform to form a first amplified waveform; and
a distributed amplifier configured to amplify the waveform based on the first amplified waveform to form a second amplified waveform.

10. The MS of claim 9, further comprising:
a transmitter configured to transmit the second amplified waveform.

11. The MS of claim 9, wherein the filter removes noise introduced by the detector.

12. The MS of claim 9, wherein a first characteristic of the one or more characteristics is a minimum voltage of the distributed amplifier;

13. The MS of claim 9, wherein a second characteristic of the one or more characteristics is a linearity of the distributed amplifier;

14. The MS of claim 9, wherein the distributed amplifier comprises one of a plurality of field effect transistors and a plurality of bipolar junction transistors.

15. A Base Station (BS) configured to amplify a waveform, the BS comprising:
a digital signal processor configured to:
detect an envelope of the waveform to form an envelope waveform; and
shape the envelope waveform to form a shaped waveform based on one or more characteristics of a distributed amplifier;
a filter configured to filter the shaped waveform to form a filtered waveform;
an envelope amplifier configured to amplify the filtered waveform to form a first amplified waveform; and
a distributed amplifier configured to amplify the waveform based on the first amplified waveform to form a second amplified waveform.

16. The BS of claim 15, further comprising:
a transmitter configured to transmit the second amplified waveform.

17. The BS of claim 15, wherein the filter removes noise introduced by a digital to analog conversion of the shaped waveform.

18. The BS of claim 15, wherein a first characteristic of the one or more characteristics is a minimum voltage of the distributed amplifier;

19. The BS of claim 15, wherein a second characteristic of the one or more characteristics is a linearity of the distributed amplifier;

20. The BS of claim 15, wherein the distributed amplifier comprises one of a plurality of field effect transistors and a plurality of bipolar junction transistors.
